(19) United States
(12) Patent Application Publication
(10) Pub. No.: US 2015/0371884 A1
(43) Pub. Date: Dec. 24, 2015

(54) Concentric Stiffener Providing Warpage Control To An Electronic Package

(71) Applicant: Avago Technologies General IP (Singapore) Pte. Ltd, Singapore (SG)

(72) Inventors: Walter Dauksher, Fort Collins, CO (US); Adam Gallegos, Fort Collins, CO (US)

(21) Appl. No.: 14/309,416

(22) Filed: Jun. 19, 2014

(51) Int. Cl. H01L 21/67; H01L 23/00; H01L 21/66

(52) U.S. Cl. CPC H01L 21/67288; H01L 22/12; H01L 22/20; H01L 23/562; H01L 24/81; H01L 2224/81815; H01L 2224/81908

(57) ABSTRACT

Techniques or processes for reducing and/or mitigation warpage are disclosed. A method for fabricating a package includes providing a stiffener member for mounting on a substrate of the package, determining an out-of-plane displacement for the substrate at a temperature of interest, the out-of-plane displacement corresponding to warpage, and if the warpage exceeds a predetermined value, modifying at least one attribute associated with the stiffener member.

### BACKGROUND

Application specific integrated circuits (ASICs) may be packaged in various different ways depending on requirements. One requirement may be to provide a large number of interconnections. For example, ball grid array and/or “flip-chip” packaging may be used for routing a large number of interconnections between an exterior of the package and an ASIC chip mounted in the package. In one example, packaging may provide for routing about two thousand interconnections between an exterior of the package and an ASIC chip mounted in the package. While the foregoing example may be illustrative, it should be understood that number of interconnections may vary, and may increase or decrease depending upon application.

In a flip-chip structure the ASIC package can be attached to a printed circuit (PC) board using, for example, an array of solder balls. The flip-chip package can typically include a substrate to which the active circuitry, referred to as the “chip” is mounted, typically using an array of solder bumps. The substrate is typically fabricated using a multi-layer laminate structure, which includes a core material over which one or more layers are fabricated. The layers are typically fabricated on opposing sides of the core and generally include one or more power planes, ground planes, signal traces, vias, and other electrically conductive interconnect layers, non-conductive layers, conductive structures, and other layers and structures. An example of the material that forms the core includes reinforced glass fibers with resins, such as FR4, etc. An example of the material used to form the conductive layers or conductive elements and structures within layers is copper. The non-conductive layers or regions of layers typically comprise solder mask material, also referred to as solder resist material, and can comprise epoxy resin, photosensitive resin, or other non-conductive material. The substrate structure is typically fabricated using known PC board fabrication techniques, and is typically fabricated at elevated temperature and pressure.

When attaching the package substrate to a PC board using the above-mentioned solder bumps, it may be important that the laminate structure forming the substrate remain as flat as possible to facilitate satisfactory electrical and mechanical connections. However, when the package substrate is attached to the PC board, the temperature of the assembly must be sufficiently elevated to permit the solder bumps to melt, typically referred to as the package reflow temperature. The reflow temperature typically depends on the properties of the material from which the solder bumps are formed. If the package substrate warps excessively during assembly, a sound mechanical and electrical connection from the package substrate to the PC board may be difficult to achieve.

Therefore, it would be desirable to have a way of reducing warpage in a package substrate for an ASIC.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. Where technical features in the figures, detailed description or any claim are followed by reference signs, the reference signs have been included for the sole purpose of increasing the intelligibility of the figures, detailed description, and/or claims. Accordingly, neither the reference signs nor their absence are intended to have any limiting effect on the scope of any claim elements. In the figures, each identical or nearly identical component that is illustrated in various figures is represented by a like numeral. For purposes of clarity, not every component may be labeled in every figure. In the figures:

FIG. 1A and FIG. 1B and FIG. 1C show various simplified views of a package fabricated to reduce and/or mitigate warpage.

FIG. 2 is a schematic diagram illustrating a portion of an application specific integrated circuit (ASIC) assembly.

FIG. 3 is a schematic diagram illustrating a portion of the assembly of FIG. 2.

FIG. 4 is a schematic diagram illustrating an example of a layer portion of the laminate of FIG. 3.

FIG. 5 is a schematic diagram illustrating a layer portion of the laminate of FIG. 3.

FIG. 6 is a diagram illustrating surface warpage.

FIG. 7 is a diagram illustrated reduction and/or mitigation of the surface warpage shown in FIG. 6.

FIG. 8A shows a simplified sectional side view of a package to illustrate a first selected thickness of its stiffener member and selecting other attributes to affect warpage.

FIG. 8B is a diagram illustrating reduction and/or mitigation of warpage for the package as shown in FIG. 8A.

FIG. 9A and FIG. 9B and FIG. 9C are various simplified sectional side views illustrating substrate warpage of the package shown in FIG. 8A

FIG. 10A is a flipped or inverted view of FIG. 9A showing the package.

FIG. 10B is a further simplified view of FIG. 10A.

FIG. 11A is a flipped or inverted view of FIG. 9B showing the package

FIG. 11B is a further simplified view of FIG. 11A.

FIG. 12A shows a simplified sectional side view of a package to illustrate a second selected thickness of its stiffener member and selecting other attributes to affect warpage.

FIG. 12B is a diagram illustrating reduction and/or mitigation of warpage for the package as shown in FIG. 12A.

FIG. 13A and FIG. 13B and FIG. 13C are various simplified sectional side views illustrating substrate warpage of the package shown in FIG. 12A

FIG. 14 shows a simplified sectional side view of a package so as to illustrate various thicknesses for its stiffener member.

FIG. 15A illustrates a system to selectively control attach temperature of a stiffener member of a package so as to affect warpage.

FIG. 15B is a diagram illustrating reduction and/or mitigation of warpage by selecting attach temperature using the system shown in FIG. 15A.

FIG. 16 is a flowchart describing the operation of an embodiment of the system and method for fabricating the package.

FIG. 17 is a flowchart describing the operation of another embodiment of the system and method for fabricating the package.

FIG. 18 is a block diagram illustrating an example general purpose computer system for implementing the system and method for fabricating the package.

### DETAILED DESCRIPTION OF EMBODIMENTS OF THE INVENTION

A system and method for fabricating a laminate structure can be used in any application specific integrated circuit (ASIC) in which it is desirable to have a stable mounting package. Further, the system and method for fabricating a package can be used to fabricate a package for any application in which warpage predictability and stability is desirable. In particular, the system and method for fabricating a package can be implemented for a package having a package substrate comprising a laminate structure.

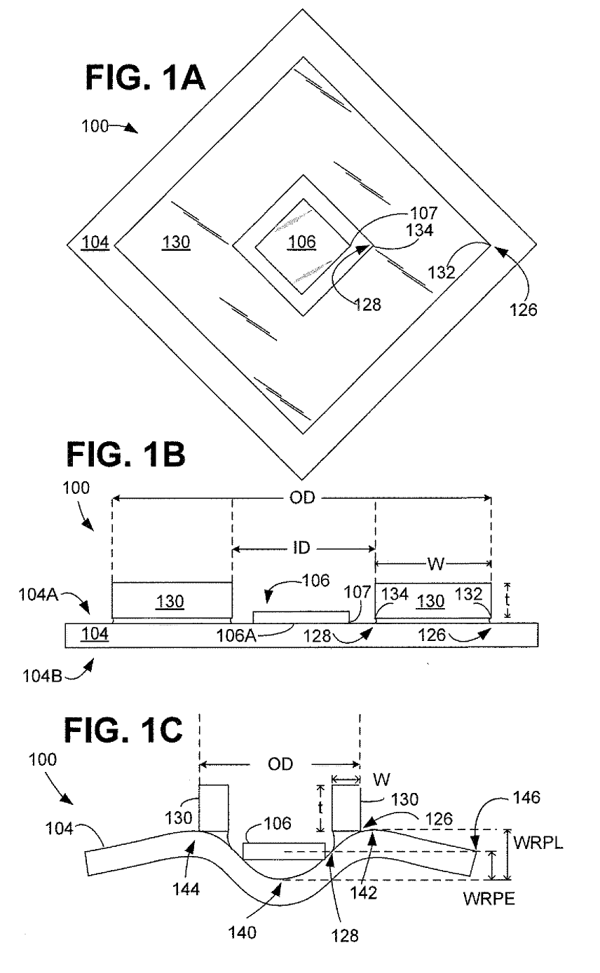

FIG. 1A and FIG. 1B and FIG. 1C show various simplified views of a package 100 fabricated to reduce and/or mitigate warpage. FIG. 1A shows a simplified top view of package 100. FIG. 1B shows a simplified sectional side view of package 100. FIG. 1C is another simplified sectional side view illustrating substrate warpage of the package 100 shown in FIG. 1B.

As shown in the figures, package 100 may comprise a first major surface 104A of a substrate 104. As will be discussed in greater detail subsequently herein, the substrate 100 may comprise a multi-layer laminate structure. A chip 106 and a stiffener member 130 may both be mounted on the first major surface 104A of the substrate 104.

To provide for attachment and/or mounting to the first major surface 104A of the substrate, a major surface 106A of the chip 106 may extend contiguously between extremities of the perimeter 107 of the chip. To provide for such attachment and/or mounting, the first major surface 104A of the substrate 104 may be arranged to extend contiguously along the major surface 106A of the chip 106 between extremities of the perimeter 107 of the chip. As will be discussed in greater detail subsequently herein, for example, solder bumps (not shown in FIGS. 1A-1C) may be used to mount and/or attach the major surface 106A of the chip to the first major surface 104A of the substrate 104.

The substrate 104 may have a substantially opposing major surface 104B, arranged substantially opposing the first major surface 104A, where the chip 106 is mounted and/or attached. As shown in the figures, the substantially opposing major surface 104B may be adjacently contiguous in a similar manner as the first major surface 104A is contiguous. The substantially opposing major surface 104A of the substrate 104 may be arranged to extend adjacently contiguous along the major surface 106A of the chip 106 between extremities of the perimeter 107 of the chip. As will be discussed in greater detail subsequently herein, for example, solder balls (not shown in FIGS. 1A-1C) may be used to mount and/or attach the substantially opposing surface 104B of the substrate 104 to a printed circuit (PC) board (not shown in FIGS. 1A-1C).

As shown, the stiffener member 130 may be substantially annular having an outer perimeter 132 and an inner perimeter 134. The stiffener member may be a formed and/or shaped as a substantially square annulus. The outer perimeter 132 may have an outer diameter OD and the inner perimeter 134 may have an inner diameter ID. The outer perimeter 132 and the inner perimeter 134 of the stiffener member 130 may be arranged in a substantially concentric arrangement relative to a perimeter 107 of the chip 106.

As shown in the figures, the stiffening member 130 may be mounted on the first major surface 104A of the substrate 104 so that a portion of the outer perimeter 132 of the stiffener member 130 may be adjacent to a first selected surface location 126 of the substrate 104, and so that a portion of the inner perimeter 134 of the stiffener member 130 may be adjacent to a second selected surface location 128 of the substrate.

As a general matter, the second selected surface location 128 may be proximate to the perimeter 107 of the chip 106. More proximate may be more desirable for mitigating and/or reducing warpage. However, various considerations and/or design rules may limit increasing proximity of the second selected surface location 128 to the perimeter 107 of the chip 106. For example, there may be limits as to how much proximity can be increased, because there may be a need to provide adequate space for surface mounting capacitors (not shown) on the substrate 104, between the inner perimeter 134 of the stiffener member 130 and the outer perimeter 107 of the chip 106. Alternatively or additionally, there may be a need to provide adequate space between the inner perimeter 134 of the stiffener member 130 and the outer perimeter 107 of the chip 106 for a syringe needle or other resin or sealant applicator, for applying resin or sealant at the perimeter 107 of the chip 106. Alternatively or additionally, there may be a need to provide adequate space between the inner perimeter 134 of the stiffener member 130 and the outer perimeter 107 of the chip 106 to provide for manufacturing and/or placement tolerances and/or thermal expansion for the chip 106 and/or stiffener member 130. Taking the foregoing into account, the inner diameter ID of the stiffener member 130 may be, for example, about twenty-nine millimeters, and the second selected surface location 128 may be located about half that distance, for example about fourteen-and-a-half millimeters measured from the central turning point of warpage, where the chip is mounted.

The stiffener member 130 may have a selected width dimension W extending between the outer perimeter 132 and the inner perimeter of the stiffener member 130. The selected width dimension W of the stiffener member 130 may be arranged to extend approximately between the first selected surface location 126 of the substrate 104 and the second selected surface location 128 of the substrate 104. To provide for attachment and/or mounting to the first major surface 104A of the substrate, the first major surface 104A of the substrate 104 may be arranged to extend contiguously along the width dimension W of the stiffener member 130, between extremities of the outer perimeter 132 and the inner perimeter 134 of the stiffener member 130 (and/or between extremities of the outer diameter OD and the inner diameter of the stiffener member 130.)

Further, as shown in the figures, the first major surface 104A of the substrate 104 may be arranged to extend contiguously between extremities of the outer perimeter 132 (and/or between extremities of the outer diameter OD of the stiffener member 130) and along the major surface 106A of the chip 106, between extremities of the perimeter 107 of the chip 106. The stiffener member 130 may have a selected thickness dimension t extending outwardly from the surface of the substrate 104, where the stiffener member 130 may be mounted at the first and second selected surface locations 126, 128 of the substrate 104.

The stiffener member 130 may be mounted at the first and second selected surface locations 126, 128 of the substrate 104 at a selected attach temperature. A suitable curable adhesive may be used. For example, the adhesive may be cured at the selected attach temperature.

Further, warpage may be affected at a particular temperature of interest. For example, a first temperature of interest may comprise a reflow temperature of solder for mounting the package 100. From the foregoing, it should be understood that package 100 may be fabricated in various ways to reduce and/or mitigate warpage at the first temperature of interest.

The substrate 104 may have out-of-plane displacement at the first temperature of interest corresponding to warpage. However, warpage for the first temperature of interest may be reduced and/or mitigated by selecting and/or adjusting and/or modifying various parameters and/or various attributes associated with the stiffener member 130 of the package 100. In particular, warpage for the first temperature of interest may be affected by one or more of: the first and second selected surface locations 126, 128 of the substrate 104 where the stiffener member 130 is mounted; the width W of the stiffener member; the thickness t of stiffener member 130, and the attach temperature of the stiffener member.

As will be discussed in greater detail subsequently herein, the chip 106 and the stiffener member 130 may be mounted on the surface of the substrate 104 so that the substrate may have out-of-plane displacement at the first temperature of interest corresponding to warpage. The stiffener member 130 may be mounted so that a portion of the outer perimeter 132 of the stiffener member 130 is adjacent to the first selected location 126.

As shown in FIG. 1C, at least a portion of the first major surface of the substrate 104 may have substantially w-shaped warpage for the first temperature of interest. In FIG. 1C and elsewhere in various other figures, the drawing sheet may be rotated or inverted for ease of recognition of the substantially w-shaped warpage. The substantially w-shaped warpage may have a central turning point 140 of warpage proximate to the chip 106, which may be interposed between first and second lateral turning points 142, 144 of warpage. More generally, central turning point 140 of warpage may be interposed between first and second lateral stationary points 142, 144 of warpage. First and second lateral stationary points 142, 144 may comprise first and second lateral turning points 142, 144 as shown in FIG. 1C, or may comprise first and second lateral inflection points as shown in other figures. The first selected surface location 126 may be proximate to one of the lateral turning points of warpage. The stiffener member 130 may be mounted at the first selected location 126 to mitigate warpage measurable from the central turning point 140. Since FIG. 1A and FIG. 1B are simplified views, the foregoing warpage is not explicitly shown in FIG. 1A and FIG. 1B, but is representatively illustrated in FIG. 1C. Further, since warpage may be small, for example on the order of tens or hundreds of microns, for ease of illustration, warpage may be exaggerated as depicted in the figures.

Accordingly, in light of the foregoing, it should be understood that FIG. 1C representatively illustrates chip 106 and stiffener member 130 mounted on the first major surface of substrate 104 so that the substrate has out-of-plane displacement at the first temperature of interest corresponding to warpage, wherein at least a portion of the first major surface of the substrate may have substantially w-shaped warpage having a central turning point 140 of warpage proximate to the chip and interposed between first and second lateral turning points 142, 144 of warpage. The first selected location 126 may be selected proximate to one of the lateral turning points 142 of warpage.

Selecting the first selected location 126 for mounting the stiffener member 130 on the surface of the substrate 104 may comprise determining out-of-plane displacement at the first temperature of interest corresponding to warpage measurable from the central turning point 140 of warpage, and adjusting the first selected location 126 to substantially reduce warpage measurable from the central turning point 140 of warpage, if warpage measurable from the central turning point 140 exceeds a first predetermined value corresponding to the first temperature of interest.

The stiffener member 130 may be mounted at the first selected location for mitigating and/or reducing warpage measurable from the central turning point 140. Warpage may be measured respectively from the central turning point 140 for determining warpage reduction and/or mitigation, and for determining whether warpage exceeds a predetermined value. For example, in FIG. 1C, warpage WRPE may be measurable from the central turning point 140 to extremity 146, and/or warpage WRPL may be measurable from the central turning point 140 to at least one of the of lateral turning points 142. Moreover, for determining warpage reduction and/or mitigation, and for determining whether warpage exceeds a predetermined value, in FIG. 1C, warpage WRPE may be measurable from the central turning point 140 to extremity 146, and/or warpage WRPL may be measurable from the central turning point 140 to at least one of the of lateral turning points 142.

In some embodiments, mitigating and/or reducing warpage measurable from the central turning point 140 may comprise reducing warpage WRPE measurable from the central turning point 140 to extremity 146 of the substrate, so as to be approximately less than warpage WRPL measurable from the central turning point 140 to one of the lateral turning points 142.

In some embodiments, out-of-plane displacement at the first temperature of interest corresponding to warpage measurable from the central turning point may be determined; and if out-of-plane displacement at the first temperature of interest exceeds a first predetermined value, the stiffener member may be modified to reduce warpage.

Modifying the stiffener member 130 may comprise altering at least one property of the stiffener member 130. For example, the stiffener member property may be attach temperature of the stiffener member 130 to the substrate 104, a thickness dimension t of the stiffener member 130, and/or width dimension W of the stiffener member 130. Alternatively or additionally, one or more stiffener member properties that may be chosen for altering may at least one member from the group of attach temperature, thickness dimension t, and width dimension W.

In some embodiments, there may be one or more determinations of warpage: out-of-plane displacement at the first temperature of interest corresponding to warpage measurable from the central turning point 140 of warpage to one or more outer extremities 146 of warpage may be determined; and out-of-plane displacement at the first temperature of interest corresponding to warpage measurable from the central turning point of warpage to one or more of the first and second lateral turning points 142, 144 of warpage may be determined. The stiffener member 130 may be modified to reduce warpage, when warpage measurable from the central turning point 140 of warpage to one or more outer extremities 146 of warpage approximately exceeds warpage measurable from the central turning point 140 of warpage one or more of the first and second lateral turning points 142, 144 of warpage.

The foregoing discussions have been primarily directed to mitigating and/or reducing warpage for the package 100 at the first temperature of interest. Alternatively or additionally, warpage may be mitigated and/or reduced for the package 100 at a second temperature of interest. For example, while the first temperature of interest may be the solder reflow temperature for mounting the package 100 to a PC board, the second temperature of interest may be room temperature. Accordingly, alternatively or additionally to the foregoing, chip 105 and stiffener member 130 may be mounted on the surface of substrate 104 so that substrate 104 has out-of-plane displacement at a second temperature of interest corresponding to warpage. Out-of-plane displacement at the second temperature of interest corresponding to warpage may be determined. Further, the stiffener member 130 may be modified to reduce warpage, if the warpage exceeds a second predetermined value corresponding to the second temperature of interest.

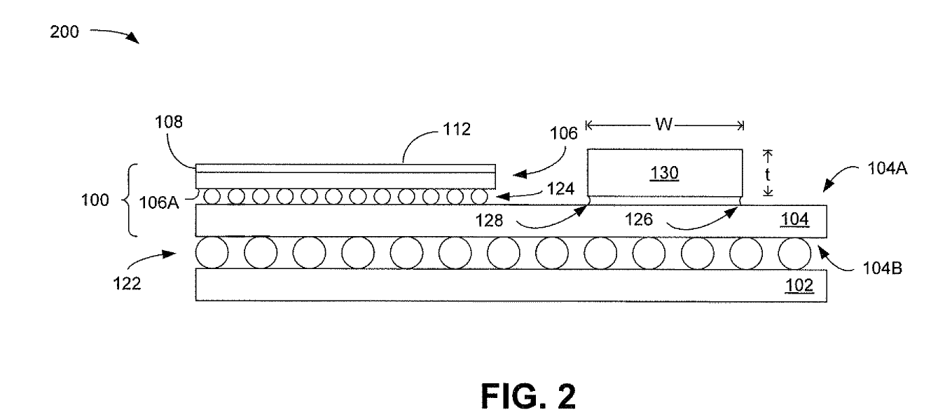

FIG. 2 is a schematic diagram illustrating a portion of an application specific integrated circuit (ASIC) assembly 200 including package substrate 104, which may comprise a laminate structure. The package substrate 104, and in particular the laminate structure, may tend to warp at various temperatures of interest.

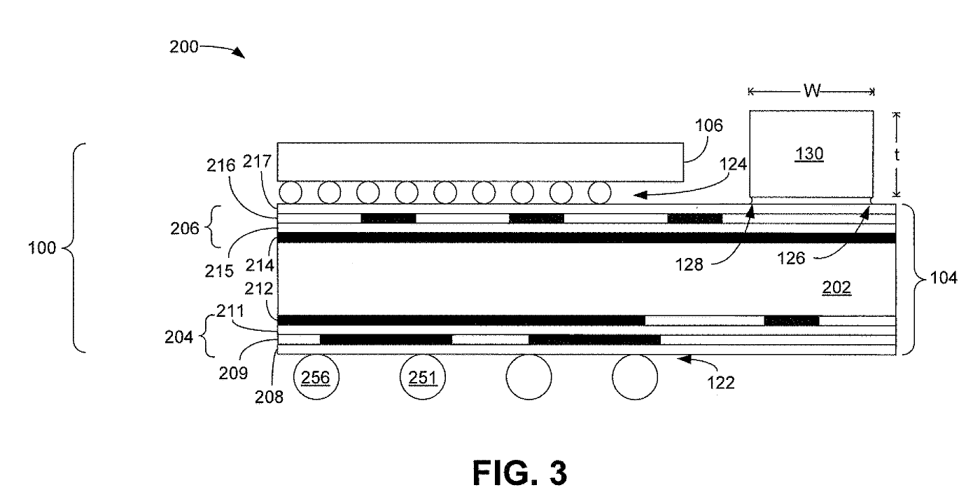

The system and method for fabricating a package may mitigate and/or reduce the warpage at one or more temperatures of interest. In particular, for the assembly 200 shown in FIG. 2 and as shown in greater detail in FIG. 3, warpage for one or more temperatures of interest may be affected by one or more of: the first and second selected surface locations 126, 128 of the substrate 104 where stiffener member 130 is mounted; the width W of the stiffener member; the thickness t of stiffener member 130, and the attach temperature of the stiffener member.

As shown in FIG. 2, the assembly 200 may comprise printed circuit (PC) board 102 over which a circuit package 100 may be located and attached to the PC board 102 using solder attachment members 122 (for example solder balls 122). An example of a circuit package 100 can be a DRAM package, and ASIC package or another circuit package. Further, the circuit package 100 may comprise flip-chip package technology, or other circuit package technology as known to those skilled in the art. The PC board 102 can be any single-layer or multi-layer structure used to mount a circuit package, such as the circuit package 100. The solder balls 122 are an example of an attachment structure that can be used to electrically and mechanically attach the circuit package 100 to the PC board 102.

The circuit package 100 comprises a circuit element, also referred to as “chip” 106, which may be located and attached to a substrate 104 using solder bumps 124. The chip 106 generally comprises the active circuit elements of the ASIC circuitry. The solder bumps 124 are an example of an attachment structure that can be used to electrically and mechanically attach the chip 106 to the substrate 104.

Accordingly, from the foregoing discussion of FIG. 2 it should be understood that substrate 104 may have substantially opposing major surface 104B, arranged substantially opposing the first major surface 104A, where the chip 106 is mounted and/or attached. For example solder balls 122 may provide attachment structure 122 that can be used to electrically and mechanically attach the substantially opposing major surface 104B of the substrate 104 to the PC board 102.

The substrate 104 may generally comprise a core and one or more layers formed on one or both sides of the core, and thereby may form a laminate structure. The core and the layers formed thereon will be shown in greater detail below. The substrate 104 may generally comprise a power distribution network and signal distribution traces that may transfer power and signal connections between the PC board 102 and the chip 106. Generally, the form factor and the array of solder bumps 124 of the chip 106 may dictate that connection to the PC board 102 and the array of solder balls 122 occur through an adaptive connection. The substrate 104 can serve this adaptive connection function coupling the chip 106 to the PC board 102, and distributing the connections between the chip 106 and the PC board 102. The substrate 104 may generally comprise one or more power layers, ground plane layers, and wiring interconnects. The substrate 104 may also include one or more passages, referred to as “vias” that provide electrical connectivity between and among the various layers of the substrate 104.

In an embodiment, the package 100 may be fabricated to reduce and/or mitigate warpage of the substrate when the substrate 104 is heated to a first temperature of interest (e.g. reflow temperature), so as to allow the solder balls 122 to reflow for attaching the package 100 to the PC board 102.

In the embodiment shown, the chip 106 may be located over the substrate 104 and a periphery and/or perimeter of the chip 106 may be generally contained within the periphery and/or extremity of the substrate 104. Further, the substrate 104 may be located over the PC board 102, and a periphery and/or extremity of the substrate 104 may generally be contained within a periphery of the PC board 102.

FIG. 3 is a schematic diagram illustrating a portion 200 of the assembly of FIG. 2. The portion 200 may generally comprise portions of the circuit package 100, chip 106 and substrate 104.

The substrate 104 may generally comprise a laminate structure comprising a laminate core 202 and layers 204 and 206. For example purposes only, the laminate core 202 can be fabricated from a glass fiber material, or another suitable material known to those skilled in the art. For example purposes only, the layers 204 may comprise individual layers 208, 209, 211 and 212; and the layers 206 may comprise individual layers 214, 215, 216 and 217. The layers 204 and 206 are illustrated as each comprising four layers, but those skilled in the art will recognize that layers 204 and 206 may comprise more or fewer layers, and may each comprise a different number of layers. Moreover, the layers 204 and 206 may generally comprise a combination of conductive metal material, such as copper, and non-conductive dielectric material, such as epoxy resins, photosensitive resins, etc. An individual layer within the layers 204 and 206 may comprise only conductive material, non-conductive material, or a combination of conductive and non-conductive material. For example purposes only, conductive material in the layers 204 and 206 in FIG. 3 is depicted using the color black and non-conductive material in the layers 204 and 206 in FIG. 3 is depicted using the color white. The layers 204 and 206 may generally comprise a combination of dielectric material and material used to construct electrical interconnects including, but not limited to, copper, or other conductive material to form circuit traces and circuit pads, and other non-conductive material to form non-conductive elements and structures.

The materials within the layers 204 and 206 may be distributed so as to provide the desired electrical interconnect, electrical power delivery, electrical ground, etc. Therefore, it may be unlikely that the area and spatial distribution of material that forms the individual layers 208, 209, 211 and 212 on one side of the core 202 will be equivalent to the area and spatial distribution of material that forms the layers 214, 215, 216 and 217 on the opposite side of the core 202. Accordingly, there are differences in the area distribution, spatial distribution, volume distribution, weight, etc., of the materials in the layers 204 and 206. While the foregoing may contribute to warpage in a minor way, relatively speaking, stress from attachment of chip 106 to substrate 104 may have far greater contribution to substrate warpage, when the substrate is heated or cooled to various temperatures of interest, and in particular the first temperature of interest, e.g. the temperature at which the solder balls 122 reflow to attach the package 100 to the PC board.

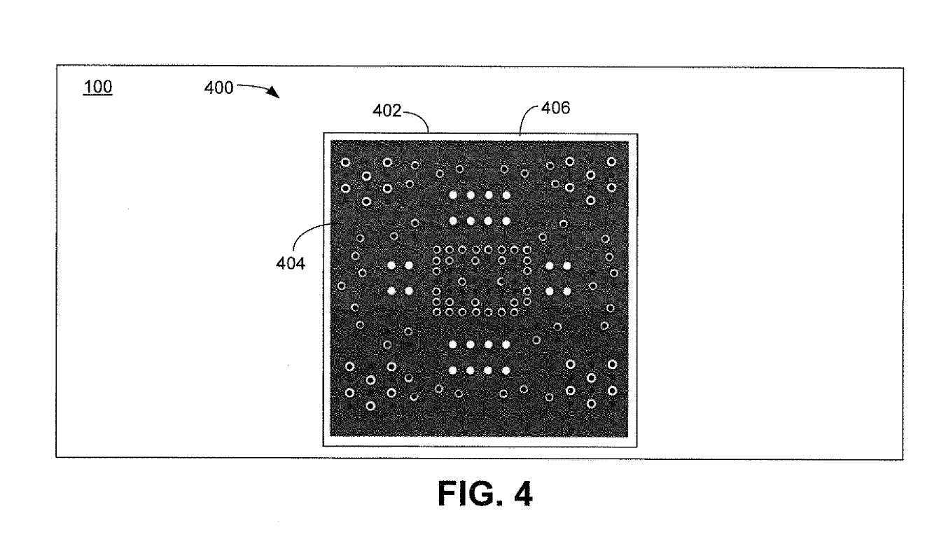

FIG. 4 is a schematic diagram 400 illustrating an example of a layer portion 402 of package 100. The layer portion 402 is an example of any of the layers 304 and 306 of package 100 shown in FIG. 3. In the embodiment shown in FIG. 4, the layer portion 402 includes portions of conductive material 404 and non-conductive material 406, the conductive material 404 and the non-conductive material 406 forming a composite layer structure. However, the layer portion 402 may include only conductive or non-conductive material. As illustrated in FIG. 4, the conductive material 404, which for example can be copper or an alloy comprising copper or other materials, is distributed within the layer portion 402 as a plane of conductive material. In this example, the conductive material 404 may comprise a power or ground plane.

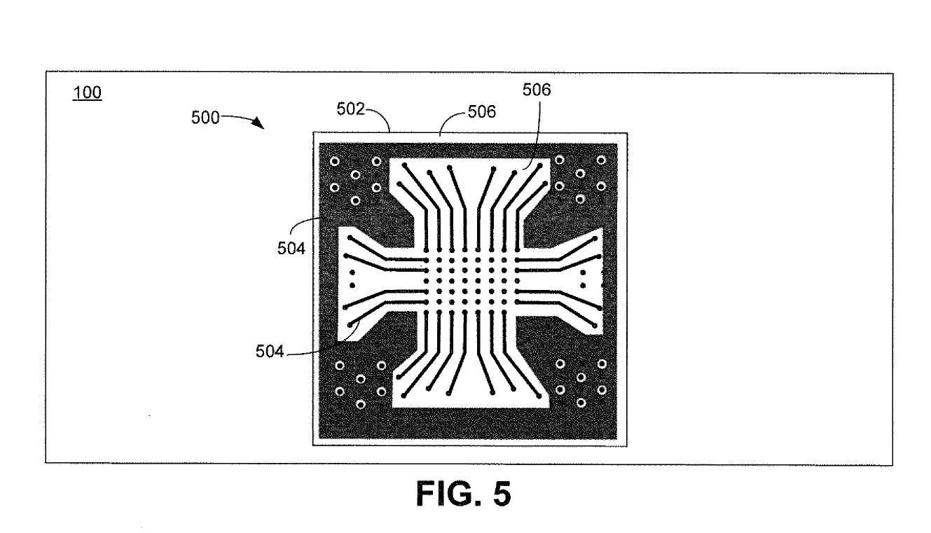

FIG. 5 is a schematic diagram 500 illustrating a layer portion of the laminate of package 100 shown in FIG. 2. The layer portion 502, in similar fashion to the layer portion 402 of FIG. 4, can be one or a portion of any of the layers 304 and 306 in FIG. 3. In FIG. 5, the conductive material is illustrated using reference numeral 504 and the non-conductive material is illustrated using reference numeral 506. The conductive material 504 and the non-conductive material 506 form a composite layer structure. As illustrated in FIG. 5, the conductive material 504 is illustrated as a series of lines, or circuit traces, which are arranged substantially in a radial pattern within the non-conductive material 506.

As employed herein, the term “out-of-plane” describes a quantity which is normal to the lateral dimension. In this example, an “out-of-plane” displacement is normal to the defined “plane” and is used to characterize warping. For example purposes only, because of this difference in the distribution of conductive material, which in this example is a metal, and a non-conductive material, which in this example can be a dielectric, between the layer portions 402 and 502, a laminate structure fabricated with the layer portion 402 on one side of the core 202, and the layer portion 402 on the opposite side of the core 202, is likely to warp at various temperatures of interest. The warpage may exceed a predetermined amount and give rise to poor mechanical and electrical connections between the substrate 104 and the PC board.

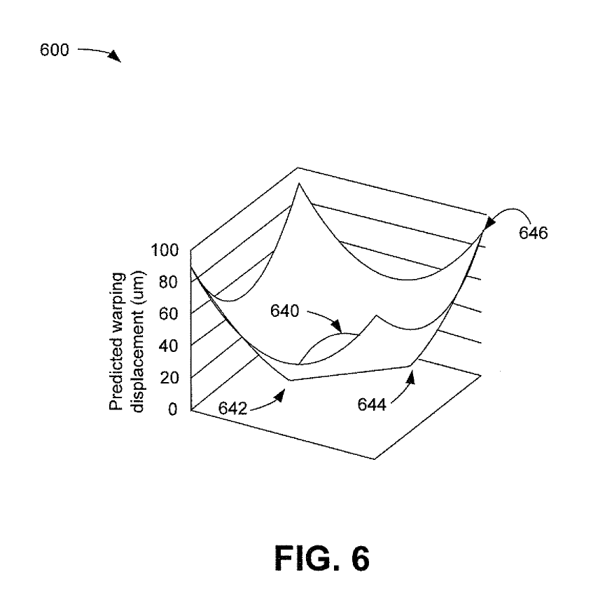

FIG. 6 is a diagram representatively illustrating warpage 600 of the surface of the substrate at the first temperature of interest. As shown in FIG. 6, the warpage 600 of the surface of the substrate may have a central turning point 640 of warpage, which may be proximate to where the chip is mounted to the surface of the substrate. The warpage 600 of the surface of the substrate may have first and second lateral turning points 642, 644 of warpage. As shown in FIG. 6, the central turning point 640 of warpage may be interposed between the first and second lateral turning points 642, 644 of warpage.

The stiffener member may be annular and may be mounted proximate to the first and second lateral turning points 642, 644 of warpage. Accordingly, it should be understood that the chip and the stiffener member may be mounted on the substrate surface so that the substrate has out-of-plane displacement at the first temperature of interest corresponding to warpage. As illustrated in the FIG. 6, at least a portion of the first major surface of the substrate may have substantially w-shaped warpage having a central turning point 640 of warpage for proximity to the chip and interposed between first and second lateral turning points 642, 644 of warpage.

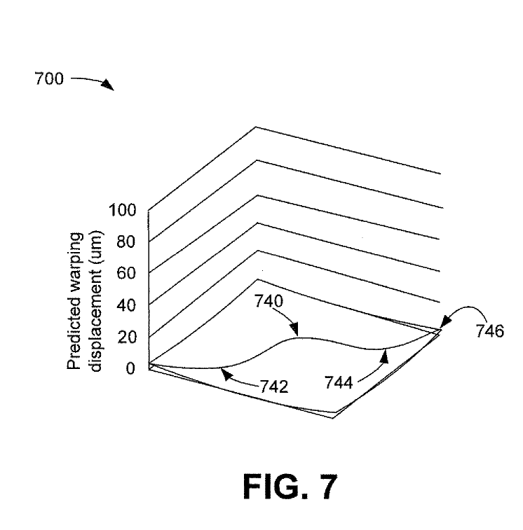

FIG. 7 is a diagram representatively illustrating relative reduction and/or mitigation of warpage of the surface of the substrate at the first temperature of interest, relative to FIG. 6. Comparison of the warpage 700 shown in FIG. 7 to the warpage 600 shown FIG. 6 illustrates reduction and/or mitigation of warpage 600 in FIG. 6 relative to warpage 700 in FIG. 7. The reduction and/or mitigation of warpage 600 in FIG. 6 relative to warpage 700 in FIG. 7 may be achieved for the first temperature of interest by selecting and/or adjusting and/or modifying one or more parameters and/or one or more attributes associated with the stiffener member of the package. Computer software simulating the stiffener and package and warpage on a computer may be used to predict warping displacement shown in microns along vertical axes in FIG. 6 and FIG. 7. In particular, reduction and/or mitigation of warpage 600 in FIG. 6 relative to warpage 700 in FIG. 7 may be affected by one or more of: the first and second selected surface locations of the substrate where the stiffener member is mounted; the width W of the stiffener member; the thickness t of stiffener member, and the attach temperature of the stiffener member.

In reviewing FIG. 6 and FIG. 7, warpages 600, 700 may be measured respectively from each of the central turning points 640, 740, for determining warpage reduction and/or mitigation, and for determining whether warpage exceeds a predetermined value. For example, in FIG. 6, warpage may be measurable from the central turning point 640 to extremity 646, and/or may be measurable from the central turning point 640 to at least one of the of lateral turning points 644. For determining warpage reduction and/or mitigation, and for determining whether warpage exceeds a predetermined value, in FIG. 7, warpage may be measurable from the central turning point 740 to extremity 746, and/or may be measurable from the central turning point 740 to at least one of the of lateral turning points 744.

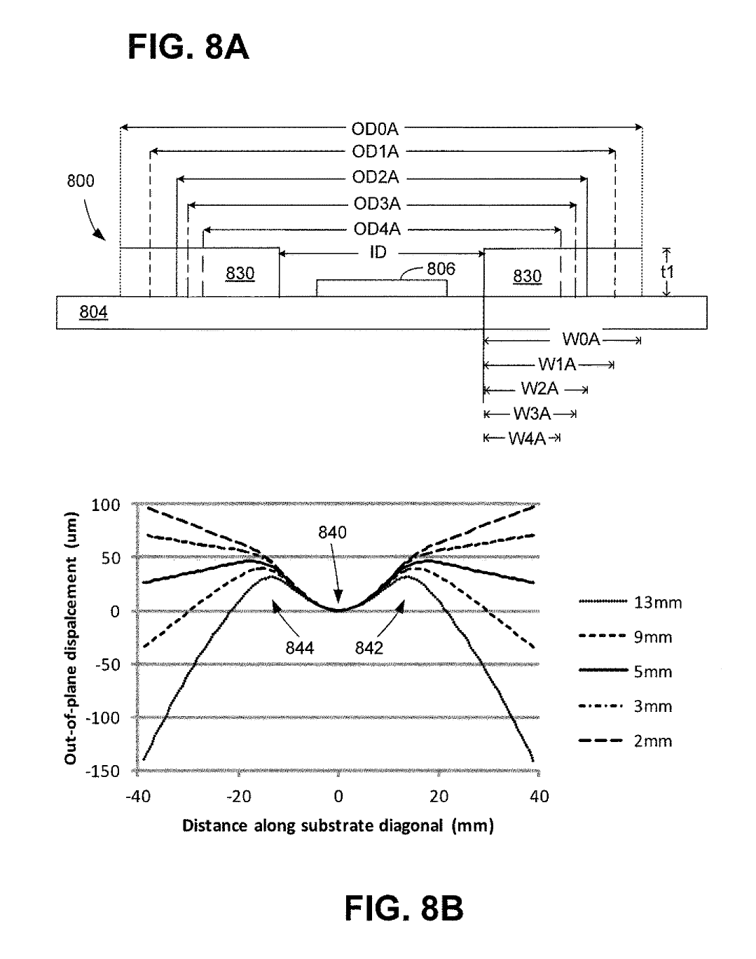

FIG. 8A shows a simplified sectional side view of package 800 to illustrate a first thickness t1 of stiffener member 830, and selecting and/or adjusting and/or modifying one or more other parameters and/or one or more other attributes associated with the stiffener member 830 of the package 800. Companion FIG. 8B is diagram illustrating reduction and/or mitigation of warpage for the first temperature of interest by selecting and/or adjusting and/or modifying one or more parameters and/or one or more attributes associated with the stiffener member of the package as shown in FIG. 8A.

Similar to what was discussed previously herein with respect to the package 100 shown in simplified sectional side view in FIG. 1B, in FIG. 8A package 800 is shown in simplified sectional side view as comprising a substrate surface of a substrate 804, a chip 806 and a substantially annular stiffener member 830 mounted on the surface of the substrate 804.

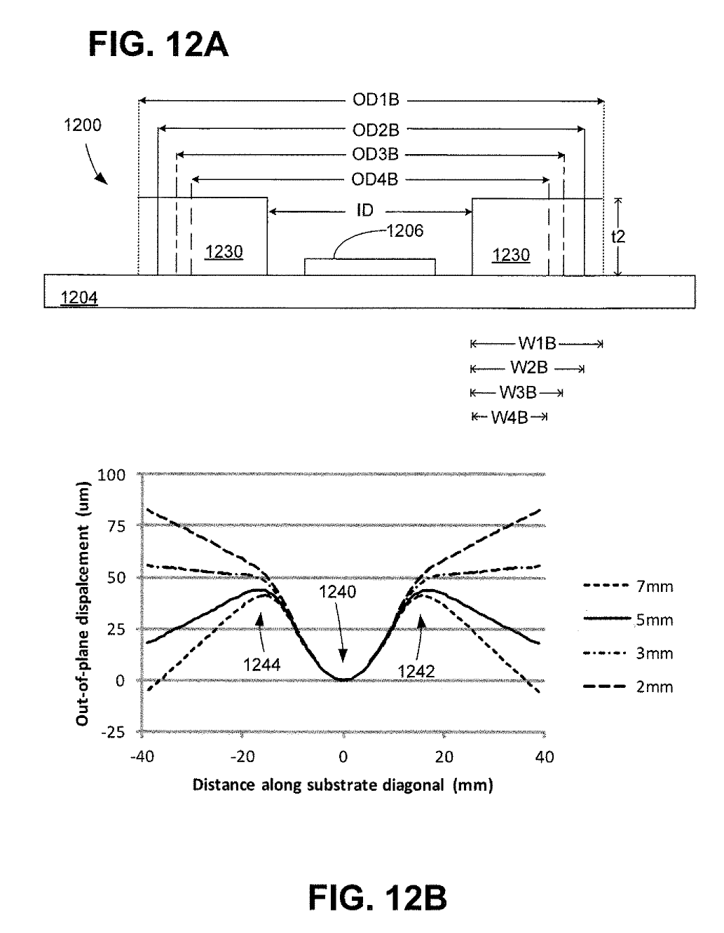

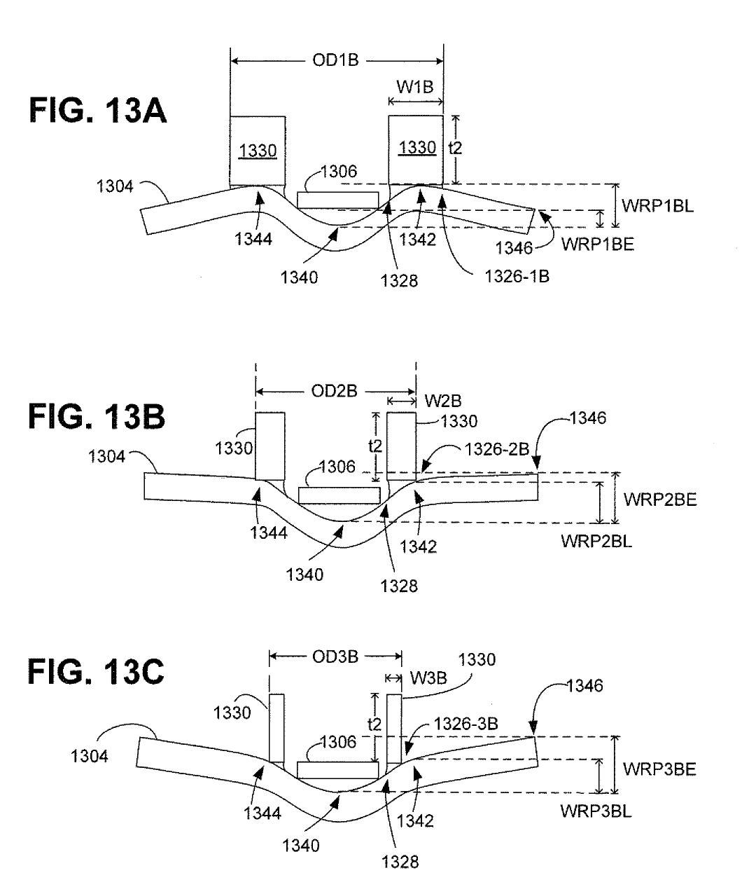

As shown in FIG. 8A, the stiffener member 830 may have a first selected thickness dimension t1 extending outwardly from the surface of the substrate. The first selected thickness dimension t1 may be for example about one millimeter or more or less, and may be varied to affect warpage. Holding the first selected thickness dimension t1 constant, for example at about one millimeter, taken together FIGS. 8A and 8B and 9A-9C and 10A-10B and 11A-11B show how warpage may be affected at the first temperature of interest by selecting and/or adjusting and/or modifying one or more other parameters and/or one or more other attributes associated with the stiffener member of the package. As will be discussed in greater detail subsequently herein, thickness may be changed from the first selected thickness dimension t1 (for example about one millimeter) to a second selected thickness dimension t2 (for example about one-and-a-half millimeter), so as to further affect warpage. Then holding the second selected thickness dimension t2 constant, for example at about one-and-a-half millimeter, FIGS. 12A and 12B and 13A-13C teach how warpage may be affected by selecting and/or adjusting and/or modifying one or more other parameters and/or one or more other attributes associated with the stiffener member of the package.

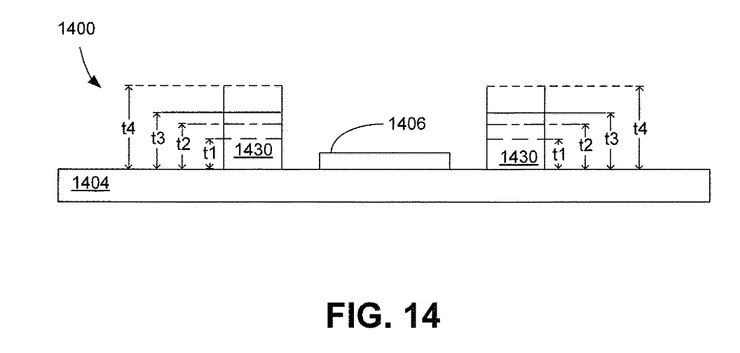

Further, as will be discussed in greater detail herein with reference to FIG. 14, thickness dimension may be varied beyond the first and second selected thickness dimensions t1, t2, to various other selected thickness dimensions to affect warpage.

As shown in FIG. 8A, the stiffener member 830 may be substantially annular having an inner diameter ID. In FIG. 8A, selected width dimensions W0A, W1A, W2A, W3A, W4A of the stiffener member 830, each corresponding to respective selected outer diameters OD0A, OD1A, OD2A, OD3A, OD4A of the stiffener member 830, may be selected and/or adjusted and/or modified and/or varied so as to affect warpage for the first temperature as illustrated in companion warpage diagram FIG. 8B.

In other words, FIG. 8B shows a family of substantially w-shaped warpage curves affected by selecting and/or adjusting and/or modifying width dimensions and corresponding outer diameters of the stiffener member 830. Each member of the family of substantially w-shaped warpage curves shown in FIG. 8B has a respective central turning point 840 of warpage interposed between first and second lateral stationary points 842, 844 of warpage. For some members of the family of substantially w-shaped warpage curves shown in FIG. 8B, first and second lateral stationary points 842, 844 may comprise first and second lateral turning points. For other members of the family of substantially w-shaped warpage curves shown in FIG. 8B, first and second lateral stationary points 842, 844 may comprise first and second lateral inflection points.

As warpage examples, a stippled line style in FIGS. 8A and 8B is used to illustrate computer simulation of predicted warpage in FIG. 8B corresponding to an example width dimension W0A of about thirteen millimeters (13 mm) and its corresponding example outer diameter OD0A in FIG. 8A. A short dashed line style in FIGS. 8A and 8B is used to illustrate computer simulation of predicted warpage in FIG. 8B corresponding to an example width dimension W1A of about nine millimeters (9 mm) and its corresponding example outer diameter OD1A in FIG. 8A. A solid line style in FIGS. 8A and 8B is used to illustrate computer simulation of predicted warpage in FIG. 8B corresponding to an example width dimension W2A of about five millimeters (5 mm) and its corresponding example outer diameter OD2A in FIG. 8A. An alternating short/long dash line style in FIGS. 8A and 8B is used to illustrate computer simulation of predicted warpage in FIG. 8B corresponding to an example width dimension W3A of about three millimeters (3 mm) and corresponding example outer diameter OD3A in FIG. 8A. A long dashed line style in FIGS. 8A and 8B is used to illustrate computer simulation of predicted warpage in FIG. 8B corresponding to an example width dimension W4A of about two millimeters (2 mm) and corresponding example outer diameter OD4A in FIG. 8A.

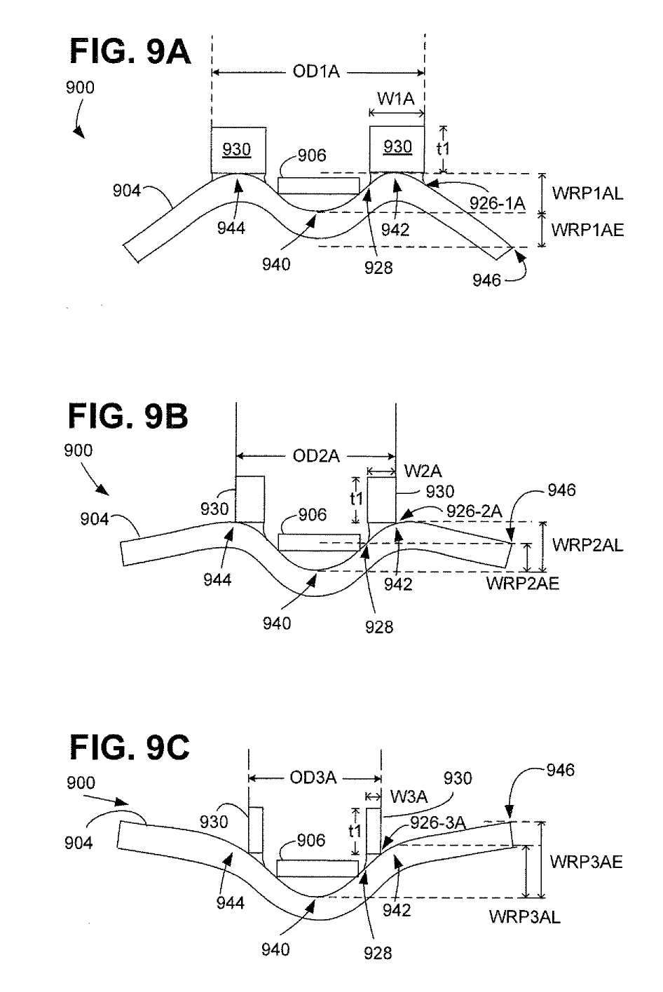

FIG. 9A and FIG. 9B and FIG. 9C are various simplified sectional side views illustrating substrate warpage of the package 900, as just discussed with respect to FIG. 8A an FIG. 8B. As shown in FIG. 9A and FIG. 9B and FIG. 9C, at least a portion of the first major surface of the substrate 904 of package 900 may have substantially w-shaped warpage for the first temperature of interest. The substantially w-shaped warpage may have central turning point 940 of warpage proximate to the chip 906 and interposed between first and second lateral stationary points 942, 944 of warpage. Accordingly, in light of the foregoing, it should be understood that FIG. 9A and FIG. 9B and FIG. 9C representatively illustrate chip 906 and stiffener member 930 mounted on the first major surface of substrate 904 so that the substrate has out-of-plane displacement at the first temperature of interest corresponding to warpage, wherein at least a portion of the first major surface of the substrate 904 has substantially w-shaped warpage having central turning point 940 of warpage proximate to the chip 906 and interposed between first and second lateral stationary points 942, 944 of warpage. The first selected location 926 may be selected proximate to one of the lateral stationary points 942 of warpage. The stiffener member 930 may be mounted at the first selected location 926 to mitigate warpage measurable from the central turning point 940.

More generally, FIG. 9A and FIG. 9B and FIG. 9C show how warpage may be affected and/or mitigated and/or reduced for the first temperature of interest by selecting and/or adjusting and/or modifying one or more parameters and/or one or more attributes associated with the stiffener member 930 of package 900. For example, at the first temperature of interest and for the first thickness dimension t1, the first selected surface location may be arranged proximate to one of the lateral stationary points of warpage and may be selectively varied along with outer diameter and width dimension of the stiffener member 930, so as to affect warpage as shown in FIG. 9A and FIG. 9B and FIG. 9C.

Selecting the first selected location 926 for mounting the stiffener member 930 on the surface of the substrate 904 may comprise determining out-of-plane displacement at the first temperature of interest corresponding to warpage measurable from the central turning point 940 of warpage, and adjusting the first selected location 926-1A shown in FIG. 9A to the varied first selected location 926-2A shown in FIG. 9B, so as to substantially reduce warpage measurable from the central turning point 940 of warpage, if warpage measurable from the central turning point 940 exceeds a first predetermined value corresponding to the first temperature of interest.

For example, in FIG. 9A, the first selected location 926-1A and first selected width dimension W1A of the stiffener member 930, and first selected outer diameter OD1A of the stiffener member 930, may be selectively varied and/or adjusted and/or modified so as to affect warpage for the first temperature of interest as illustrated FIGS. 9B and 9C. In other words, the foregoing of FIG. 9A may be selectively varied as shown in FIGS. 9B and 9C, so as to provide varied first selected surface locations 926-2A, 926-3A along with varied outer diameters OD2A, OD3A and varied width dimensions W2A, W3A of the stiffener member 930, so as to affect warpage as shown in FIG. 9B and FIG. 9C.

For example, in FIG. 9B, the varied first selected location 926-2A and the varied width dimension W2A and the varied outer diameter OD2A of the stiffener member 930 may be compared to what is shown in FIG. 9A. Similarly, in FIG. 9C, there is shown further variation for first selected location 926-3A and further varied width dimension W3A and further varied outer diameter OD3A of the stiffener member 930, which may be compared to what is shown in FIG. 9A.

For comparison purposes, as measured distance from the central turning point 940 of warpage, the first selected location 926-1A in FIG. 9A may be located (for example) about twenty-three-and-a-half millimeters from the central turning point 940 of warpage, while the varied first selected location 926-2A in FIG. 9B may be located (for example) about nineteen-and-a-half millimeters from the central turning point 940 of warpage, and the further varied first selected location 926-3A in FIG. 9C may be located (for example) about twelve-and-a-half millimeters from the central turning point 940 of warpage.

Similarly, for comparison purposes, the first selected width dimension W1A in FIG. 9A may be for example about nine millimeters, while the varied width dimension W2A in FIG. 9B may be about five millimeters, and the further varied width dimension W3A in FIG. 9C may be about three millimeters. Similarly, for comparison purposes, the outer diameter OD1A in FIG. 9A may be for example about forty-seven millimeters, while the varied outer diameter OD2A in FIG. 9B may be about thirty-nine millimeters, and the further varied outer diameter OD3A in FIG. 9C may be about thirty-five millimeters.

Warpage may be measured respectively from central turning point 940 for determining warpage reduction and/or mitigation, and for determining whether warpage exceeds a predetermined value. For example, in FIG. 9A, warpage WRP1AE may be measurable from the central turning point 940 to extremity 946, and/or warpage WRP1AL may be measurable from the central turning point 940 to at least one of the of lateral turning points 942. Moreover, for determining warpage reduction and/or mitigation, and for determining whether warpage exceeds a predetermined value, in FIG. 9A, warpage WRP1AE may be measurable from the central turning point 940 to extremity 946, and/or warpage WRP1AL may be measurable from the central turning point 940 to at least one of the of lateral turning points 942.

Further, warpage in FIG. 9B for the varied first selected location 926-2A and the varied width dimension W2A and the varied outer diameter OD2A of the stiffener member 930 may be compared to warpage shown in FIG. 9A. Similarly, warpage in FIG. 9C for the further variation for first selected location 926-3A and further varied width dimension W3A and further varied outer diameter OD3A of the stiffener member may be compared to warpage shown in FIG. 9A.

For example, for comparison purposes, warpage WRP1AE measurable from the central turning point 940 to extremity 946 in FIG. 9A may be compared to warpage WRP2AE measurable from the central turning point 940 to extremity 946 in FIG. 9B, and furthermore each of the foregoing may be compared to warpage WRP3AE measurable from the central turning point 940 to extremity 946 in FIG. 9C.

Similarly, for comparison purposes, warpage WRP1AL measurable from the central turning point 940 to lateral turning point 942 in FIG. 9A may be compared to warpage WRP2AL measurable from the central turning point 940 to lateral turning point 942 in FIG. 9B, and furthermore each of the foregoing may be compared to warpage WRP3AL measurable from the central turning point 940 to lateral inflection point 942 in FIG. 9C.

Alternatively or additionally, warpage measurable from the central turning point 940 to one of the lateral turning points 942 may be mitigated so as to approximately overlap warpage measurable from the central turning point 940 to extremity 946 of the substrate 904. For example, mitigation in FIG. 9A may be desired because warpage WRP1AL and warpage WRP1AE may extend in opposing directions and/or may not be substantially overlapping. However, in FIG. 9B warpage WRP2AL measurable from the central turning point 940 to one of the lateral turning points 942 may be affected and/or mitigated so as to approximately overlap warpage WRP2AE measurable from the central turning point 940 to extremity 946 of the substrate 904. The foregoing may be achieved by: varying the first selected location 926-1A shown in FIG. 9A to the varied first selected location 926-2A shown in FIG. 9B (e.g. moving 926-1A to 926-2A so as to be more proximate/closer to central turning point 940); and/or varying and/or decreasing the first selected width dimension W1A shown in FIG. 9A to the varied width dimension W2A shown in FIG. 9B; and/or varying and/or decreasing the first selected outer diameter OD1A shown in FIG. 9A to the outer diameter OD2A as shown in FIG. 9B, so as to affect warpage for the first temperature of interest as illustrated FIG. 9B.

Alternatively or additionally, warpage measurable from the central turning point 940 to extremity 946 of the substrate 904 may be mitigated and/or reduced so as to be approximately less than warpage measurable from the central turning point 940 to one of the lateral turning points 942. For example in FIG. 9A it may be desirable to reduce warpage WRP1AE measurable from the central turning point 940 to an extremity 946 of the substrate 904 so as to be approximately less than warpage WRP1AL measurable from the central turning point 940 to one of the lateral turning points 942. The foregoing may be achieved by: varying the first selected location 926-1A shown in FIG. 9A to the varied first selected location 926-2A shown in FIG. 9B (e.g. moving 926-1A to 926-2A so as to be more proximate/closer to central turning point 940); and/or varying and/or decreasing the first selected width dimension W1A shown in FIG. 9A to the varied width dimension W2A shown in FIG. 9B; and/or varying and/or decreasing the first selected outer diameter OD1A shown in FIG. 9A to the outer diameter OD2A as shown in FIG. 9B, so as to affect warpage for the first temperature of interest as illustrated FIG. 9B.

Comparing FIG. 9B relative to FIG. 9A, warpage WRP2AE in FIG. 9B is shown as reduced relative to warpage WRP1AE in FIG. 9A. Moreover, FIG. 9B shows warpage WRP2AE measurable from the central turning point 940 to extremity 946 of the substrate 904 as being reduced, so as to be substantially and/or approximately less than warpage WRP2AL measurable from the central turning point 940 to one of the lateral turning points 942.

While there may be some benefits in reducing volume/weight of stiffener member 930 from ongoing or continued decreasing of its width dimension/outer diameter/first selected location to central distance, this may also be done while maintaining extremity warpage WRP2AE so as to be substantially and/or approximately less than lateral turning point warpage WRP2AL as shown in FIG. 9B. Excessive decreasing of width dimension/outer diameter/first selected location to central distance as shown in FIG. 9C may result in increasing warpage, as extremity warpage WRP3AE may exceed lateral inflection point warpage WRP3AL as shown in FIG. 9C. Accordingly, it should be understood that width dimension/outer diameter/first selected location to central distance may be adjusted selectively.

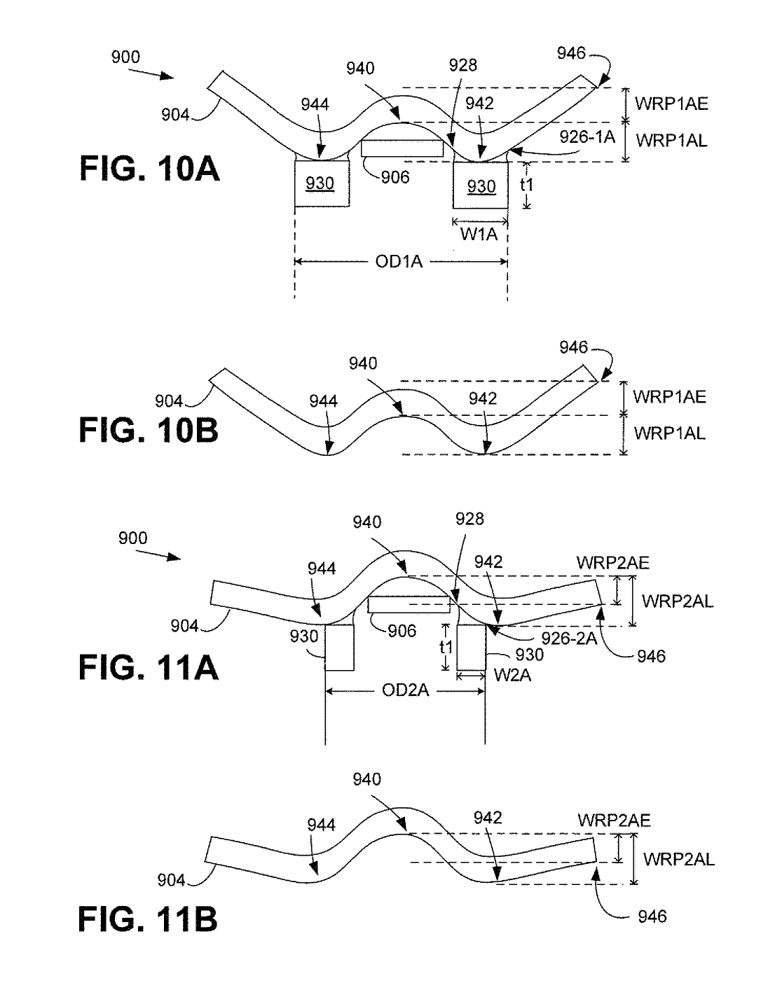

FIG. 10A is a flipped or inverted view of FIG. 9A showing package 900. FIG. 10B is a further simplified view of FIG. 10A. FIG. 11A is a flipped or inverted view of FIG. 9B showing package 900. FIG. 11B is a further simplified view of FIG. 11A. As shown in FIG. 10A and 10B and 11A and 11B, at least a portion of the first major surface of the substrate 904 of package 900 may have substantially w-shaped warpage for the first temperature of interest. The substantially w-shaped warpage may have central turning point 940 of warpage proximate to the chip 906 and interposed between first and second lateral turning points 942, 944 of warpage. Accordingly, in light of the foregoing, it should be understood that FIG. 10A and 10B and 11A and 11B representatively illustrate chip 906 and stiffener member 930 mounted on the first major surface of substrate 904 so that the substrate has out-of-plane displacement at the first temperature of interest corresponding to warpage, wherein at least a portion of the first major surface of the substrate has substantially w-shaped warpage having central turning point 940 of warpage proximate to the chip 906 and interposed between first and second lateral turning points 942, 944 of warpage.

FIG. 12A shows a simplified sectional side view of package 1200 to illustrate a changed/second thickness t2 of stiffener member 1230, and further selecting and/or adjusting and/or modifying one or more parameters and/or one or more attributes associated with stiffener member 1230 of package 1200. Companion FIG. 12B is a diagram illustrating reduction and/or mitigation of warpage for the first temperature of interest and the second thickness t2 by selecting and/or adjusting and/or modifying one or more parameters and/or one or more attributes associated with the stiffener member of the package as shown in FIG. 12A.

As mentioned previously herein, FIGS. 12A and 12B and 13A-13C show thickness as being changed from the first selected thickness dimension t1 (for example about one millimeter) shown in previous figures to a second selected thickness dimension t2 (for example about one-and-a-half millimeters) as shown in FIGS. 12A and 12B and 13A-13C, so as to further affect warpage. Now holding the second selected thickness dimension t2 constant, for example at about one-and-a-half millimeter, FIGS. 12A and 12B and 13A-13C show how warpage may be affected by selecting and/or adjusting and/or modifying one or more other parameters and/or one or more other attributes associated with the stiffener member of the package.

Similar to what was discussed previously herein with respect to the package 800 shown in simplified sectional side view in FIG. 8A, in FIG. 12A package 1200 is shown in simplified sectional side view as comprising a substrate surface of a substrate 1204, a chip 1206 and a substantially annular stiffener member 1230 mounted on the surface of the substrate 1204.

As shown in FIG. 12A, the stiffener member 1230 may have a second selected thickness dimension t2 extending outwardly from the surface of the substrate. The second selected thickness dimension t2 may be for example about one-and-a-half millimeter or more or less, and may be varied to affect warpage. Holding the second selected thickness dimension t2 constant, for example at about one-and-a-half millimeter, taken together FIGS. 12A and 12B and 13A-13C show how warpage may be affected at the first temperature of interest by selecting and/or adjusting and/or modifying one or more other parameters and/or one or more other attributes associated with the stiffener member of the package.

As shown in FIG. 12A, the stiffener member 1230 may be substantially annular having an inner diameter ID. In FIG. 12A, selected width dimensions W1B, W2B, W3B, W4B of the stiffener member 1230, each corresponding to respective selected outer diameters OD1B, OD2B, OD3B, OD4B of the stiffener member 1230, may be selected and/or adjusted and/or modified and/or varied so as to affect warpage for the first temperature as illustrated in companion warpage diagram FIG. 12B.

In other words, FIG. 12B shows a family of substantially w-shaped warpage curves affected by selecting and/or adjusting and/or modifying width dimensions and corresponding outer diameters of the stiffener member 1230. Each member of the family of substantially w-shaped warpage curves shown in FIG. 12B has a respective central turning point 1240 of warpage interposed between first and second lateral stationary points 1242, 1244 of warpage. For some members of the family of substantially w-shaped warpage curves shown in FIG. 12B, first and second lateral stationary points 1242, 1244 may comprise first and second lateral turning points. For other members of the family of substantially w-shaped warpage curves shown in FIG. 12B, first and second lateral stationary points 1242, 1244 may comprise first and second lateral inflection points.

As examples of warpage, a stippled line style in FIGS. 12A and 12B is used to illustrate computer simulation of predicted warpage in FIG. 12B corresponding to an example width dimension W1B of about seven millimeters (7 mm) and its corresponding example outer diameter OD1B in FIG. 12A. A solid line style in FIGS. 12A and 12B is used to illustrate computer simulation of predicted warpage in FIG. 12B corresponding to an example width dimension W2B of about five millimeters (5 mm) and its corresponding example outer diameter OD2B in FIG. 12A. An alternating short/long dash line style in FIGS. 12A and 12B is used to illustrate computer simulation of predicted warpage in FIG. 12B corresponding to an example width dimension W3B of about three millimeters (3 mm) and corresponding example outer diameter OD3B in FIG. 12A. A long dashed line style in FIGS. 12A and 12B is used to illustrate computer simulation of predicted warpage in FIG. 12B corresponding to an example width dimension W4B of about two millimeters (2 mm) and corresponding example outer diameter OD4B in FIG. 12A.

FIG. 13A and FIG. 13B and FIG. 13C are various simplified sectional side views illustrating substrate warpage of the package 1300, as just discussed with respect to FIG. 12A an FIG. 12B. As shown in FIG. 13A and FIG. 13B and FIG. 13C, at least a portion of the first major surface of the substrate 1304 of package 1300 may have substantially w-shaped warpage for the first temperature of interest. The substantially w-shaped warpage may have central turning point 1340 of warpage proximate to the chip 1306 and interposed between first and second lateral stationary points 1342, 1344 of warpage. Accordingly, in light of the foregoing, it should be understood that FIG. 13A and FIG. 13B and FIG. 13C representatively illustrate chip 1306 and stiffener member 1330 mounted on the first major surface of substrate 1304 so that the substrate has out-of-plane displacement at the first temperature of interest corresponding to warpage, wherein at least a portion of the first major surface of the substrate 1304 has substantially w-shaped warpage having central turning point 1340 of warpage proximate to the chip 1306 and interposed between first and second lateral stationary points 1342, 1344 of warpage. The first selected location 1326 may be selected proximate to one of the lateral stationary points 1342 of warpage. The stiffener member 1330 may be mounted at the first selected location 1326 to mitigate warpage measurable from the central turning point 1340.

More generally, FIG. 13A and FIG. 13B and FIG. 13C show how warpage may be affected and/or mitigated and/or reduced for the first temperature of interest by selecting and/or adjusting and/or modifying one or more parameters and/or one or more attributes associated with the stiffener member 1330 of package 1300. For example, at the first temperature of interest and now for the second thickness dimension t2, the first selected surface location may once again be arranged proximate to one of the lateral stationary points of warpage and may once again be selectively varied along with outer diameter and width dimension of the stiffener member 1330, so as to affect warpage as shown in FIG. 13A and FIG. 13B and FIG. 13C.

For example, in FIG. 13A, the first selected location 1326-1B and first selected width dimension W1B of the stiffener member 1330, and first selected outer diameter OD1B of the stiffener member 1330, may be selectively varied and/or adjusted and/or modified so as to affect warpage for the first temperature of interest as illustrated FIGS. 13B and 13C. In other words, the foregoing of FIG. 13A may be selectively varied as shown in FIGS. 13B and 13C, so as to provide varied first selected surface locations 1326-2B, 1326-3B along with varied outer diameters OD2B, OD3B and varied width dimensions W2B, W3B of the stiffener member 1330, so as to affect warpage as shown in FIG. 13B and FIG. 13C.

For example, in FIG. 13B, the varied first selected location 1326-2B and the varied width dimension W2B and the varied outer diameter OD2B of the stiffener member 1330 may be compared to what is shown in FIG. 13A. Similarly, in FIG. 13C, there is shown further variation for first selected location 1326-3B and further varied width dimension W3B and further varied outer diameter OD3B of the stiffener member 1330, which may be compared to what is shown in FIG. 13A.

For comparison purposes, as measured distance from the central turning point 1340 of warpage, the first selected location 1326-1B in FIG. 13A may be located (for example) about nineteen-and-a-half millimeters from the central turning point 1340 of warpage, while the varied first selected location 1326-2B in FIG. 13B may be located (for example) about seventeen-and-a-half millimeters from the central turning point 1340 of warpage, and the further varied first selected location 1326-3B in FIG. 13C may be located (for example) about sixteen-and-a-half millimeters from the central turning point 1340 of warpage.

Similarly, for comparison purposes, the first selected width dimension W1B in FIG. 13A may be for example about five millimeters, while the varied width dimension W2B in FIG. 13B may be about three millimeters, and the further varied width dimension W3B in FIG. 13C may be about two millimeters. Similarly, for comparison purposes, the outer diameter OD1B in FIG. 13A may be for example about thirty-nine millimeters, while the varied outer diameter OD2B in FIG. 13B may be about thirty-five millimeters, and the further varied outer diameter OD3B in FIG. 13C may be about thirty-three millimeters.

Warpage may be measured respectively from central turning point 1340 for determining warpage reduction and/or mitigation, and for determining whether warpage exceeds a predetermined value. For example, in FIG. 13A, warpage WRP1BE may be measurable from the central turning point 1340 to extremity 1346, and/or warpage WRP1BL may be measurable from the central turning point 1340 to at least one of the of lateral turning points 1342. Moreover, for determining warpage reduction and/or mitigation, and for determining whether warpage exceeds a predetermined value, in FIG. 13A, warpage WRP1BE may be measurable from the central turning point 1340 to extremity 1346, and/or warpage WRP1BL may be measurable from the central turning point 1340 to at least one of the of lateral turning points 1342.

Further, warpage in FIG. 13B for the varied first selected location 1326-2B and the varied width dimension W2B and the varied outer diameter OD2B of the stiffener member 1330 may be compared to warpage shown in FIG. 13B. Similarly, warpage in FIG. 13C for the further variation for first selected location 1326-3B and further varied width dimension W3B and further varied outer diameter OD3B of the stiffener member may be compared to warpage shown in FIG. 13B.

For example, for comparison purposes, warpage WRP1BE measurable from the central turning point 1340 to extremity 1346 in FIG. 13A may be compared to warpage WRP2BE measurable from the central turning point 1340 to extremity 1346 in FIG. 13B, and furthermore each of the foregoing may be compared to warpage WRP3BE measurable from the central turning point 1340 to extremity 1346 in FIG. 13C. Alternatively or additionally, warpage WRP1BE measurable from the central turning point 1340 to extremity 1346 in FIG. 13A may be compared to warpage WRP1AE measurable from the central turning point 940 to extremity 946 in FIG. 9A, and/or compared to warpage WRP2AE measurable from the central turning point 940 to extremity 946 in FIG. 9B, and/or compared to warpage WRP3AE measurable from the central turning point 940 to extremity 946 in FIG. 9C.

Similarly, for comparison purposes, warpage WRP1BL measurable from the central turning point 1340 to lateral turning point 1342 in FIG. 13A may be compared to warpage WRP2BL measurable from the central turning point 1340 to lateral inflection point 1342 in FIG. 13B, and furthermore each of the foregoing may be compared to warpage WRP3BL measurable from the central turning point 1340 to lateral inflection point 1342 in FIG. 13C. Alternatively or additionally, warpage WRP1BL measurable from the central turning point 1340 to lateral turning point 1342 in FIG. 13A may be compared to warpage WRP1AL measurable from the central turning point 940 to lateral turning point 942 in FIG. 9A, and/or may be compared to warpage WRP2AL measurable from the central turning point 940 to lateral turning point 942 in FIG. 9B, and/or may be compared to warpage WRP3AL measurable from the central turning point 940 to lateral inflection point 942 in FIG. 9C.

For example, comparing FIG. 13A relative to FIG. 9B: warpage WRP1BE measurable from the central turning point 1340 to extremity 1346 in FIG. 13A is shown as reduced relative to warpage WRP2AE in FIG. 9B; and warpage WRP1BL measurable from the central turning point 1340 to lateral turning point 1342 in FIG. 13A is shown as reduced relative to warpage WRP2AL in FIG. 9B. The foregoing was achieved by varying and/or increasing the first thickness t1 in FIG. 9B to the second thickness t2 in FIG. 13A. Accordingly, mitigating warpage measurable from the central turning point may comprise reducing both warpage measurable from the central turning point to an extremity of the substrate and warpage measurable from the central turning point to one of the lateral turning points.

FIG. 14 shows package 1400 in simplified sectional side view as comprising a substrate surface of a substrate 1404, a chip 1406 and a substantially annular stiffener member 1430 mounted on the surface of the substrate 1404, with various thicknesses for the stiffener member. As shown in FIG. 14, thickness dimension of the stiffener member may be varied beyond the first and second selected thickness dimensions t1, t2, to various other selected thickness dimensions t3, t4 to affect warpage.

While increasing thickness dimensions of the stiffener member may provide some advantages in mitigating warpage, there may also be some disadvantages such as increasing weight and volume of the stiffener member. For example, comparing what is shown and taught for FIG. 9B to what is shown and taught for FIG. 13A, although there may be some relative additional warpage mitigation benefits to relative increase in thickness dimension of the stiffener member as in FIG. 13A relative to FIG. 9B, such benefits may be outweighed by possible disadvantages in relative increased weight and volume of the stiffener member in FIG. 13A relative to FIG. 9B.

In contrast, a possible triple advantage of selectively decreasing width dimension/outer diameter/first selected location distance (while still also maintaining extremity warpage WRP2AE so as to be approximately and/or substantially less than lateral turning point warpage WRP2AL, and/or maintaining WRP2AL approximately overlapping WRP2AE) is illustrated in the changes from FIG. 9A to 9B, since warpage may be substantially and advantageously mitigated/reduced in FIG. 9B relative to FIG. 9A, while both weight and volume of the stiffener member 930 may also be substantially and advantageously reduced in FIG. 9B relative to FIG. 9A.

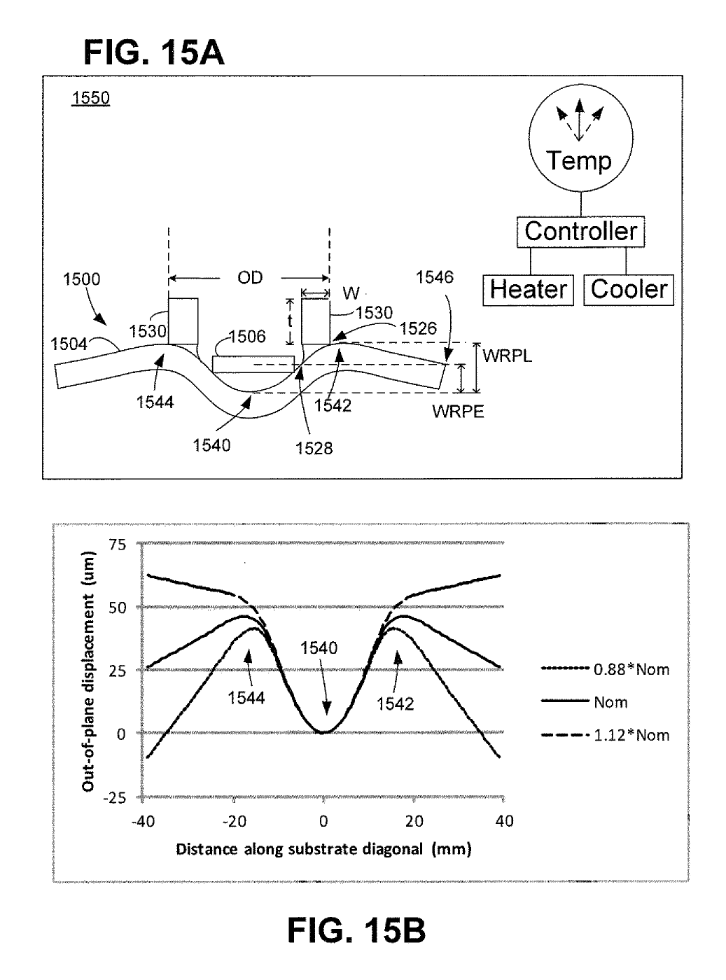

In addition to the foregoing, there may also be other ways to mitigate and/or reduce warpage at the first temperature of interest, without increasing volume/weight of the stiffener member of the package. FIG. 15A shows a simplified sectional side view of package 1500, which is generally similar to side package view as discussed previously herein. However, FIG. 15A illustrates a system 1550 including a controller to selectively control attach temperature of the stiffener member 1530. The attach temperature may be substantially different than the first temperature of interest, and may be selected so as to substantially reduce and/or mitigate warpage at the first temperature of interest. The stiffener member 1530 may be mounted at the first and second selected surface locations 1526, 1528 of the substrate 1504 at an attach temperature selected by the controller so as to mitigate and/or reduce. A suitable curable adhesive may be used. For example, the adhesive may be cured at the selected attach temperature. The controller may be a computer.

Companion FIG. 15B is a diagram illustrating reduction and/or mitigation of warpage for the first temperature of interest by selecting and/or adjusting and/or modifying attach temperature as shown in FIG. 15A. FIG. 15B shows a family of substantially w-shaped warpage curves affected by selecting and/or adjusting and/or modifying attach temperature of the stiffener member 1530. Each member of the family of substantially w-shaped warpage curves shown in FIG. 15B has a respective central turning point 1540 of warpage interposed between first and second lateral stationary points 1542, 1544 of warpage. For two members of the family of substantially w-shaped warpage curves shown in FIG. 15B, first and second lateral stationary points 1542, 1544 may comprise first and second lateral turning points. For a remaining one member of the family of substantially w-shaped warpage curves shown in FIG. 15B, first and second lateral stationary points 1542, 1544 may comprise first and second lateral inflection points.

A solid line style in FIG. 15B shows warpage corresponding to a nominal attach temperature. A stippled line style shows warpage corresponding to an attach temperature that is reduced from nominal by twelve percent. A long dashed line style shows warpage corresponding to an attach temperature that is increased from nominal by twelve percent.

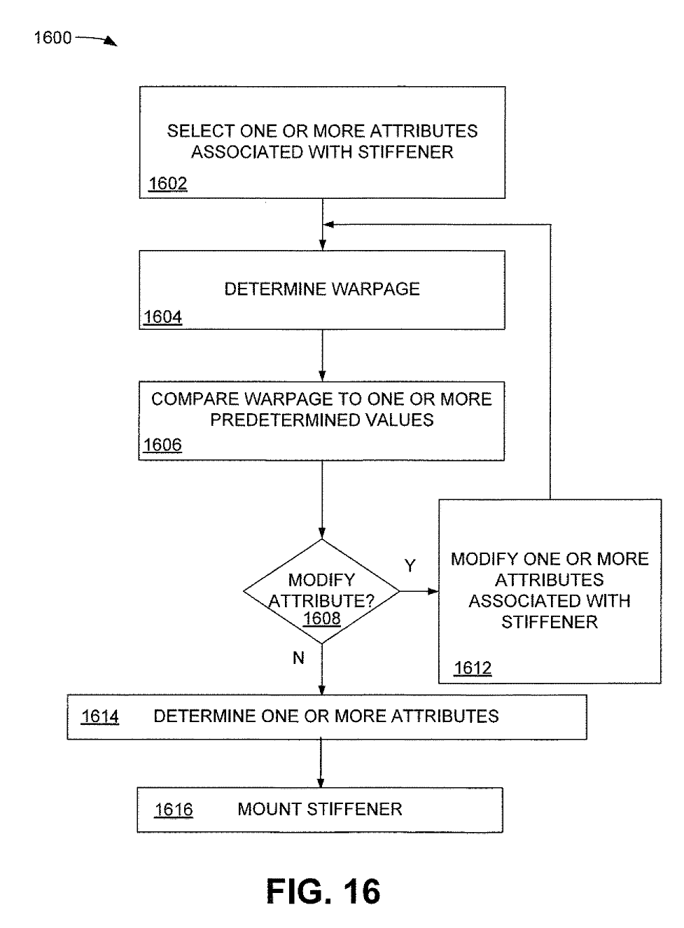

FIG. 16 is a flowchart describing the operation of an embodiment of the system and method for fabricating the package. A fabricating process 1600 according to one embodiment is shown in FIG. 16. The fabricating process 1600 may be suitable for a chip and stiffener member to be mounted on a provided surface of a substrate of the package. The substrate may have out-of-plane displacement at a first temperature of interest corresponding to warpage when the chip and stiffener member to be mounted are mounted on the substrate surface, wherein at least a portion of the substrate surface has substantially w-shaped warpage having a central turning point of warpage proximate to the chip and interposed between first and second lateral turning points of warpage, as discussed in detail previously herein. More generally, the central turning point of warpage may be interposed between first and second lateral stationary points of warpage. The first and second lateral stationary points may comprise first and second lateral turning points, or may comprise first and second lateral inflection points as discussed previously herein. The first temperature of interest may be may be the solder reflow temperature for mounting the package to a PC board.

In accordance with the fabricating process 1600 shown in FIG. 16, the process may begin with selecting a first selected location proximate to one of the lateral stationary points of warpage, wherein the stiffener member is to be mounted at the first selected location for mitigating warpage. Such first selected location may be an attribute/parameter associated with the stiffener member.

More generally, the process may begin with selecting 1600 one or more attributes/parameters associated with the stiffener member. For example, a second selected location may also be selected. As already discussed in detail previously herein, the stiffener member may be substantially annular having an outer perimeter and an inner perimeter to be mounted in a substantially concentric arrangement relative to a perimeter of the chip. The first selected location may be selected to be adjacent to a portion of the outer perimeter when the stiffener member is to be mounted on the substrate surface. The second selected location may be selected to be adjacent to a portion of the inner perimeter when the stiffener member is to be mounted on the substrate surface.

Alternatively or additionally other attributes affecting warpage already discussed in detail previously may be selected. For example, selecting 1600 one or more attributes/parameters associated with the stiffener member may comprise one or more of selecting a width dimension of the stiffener member, selecting a thickness dimension of the stiffener and/or selecting an attach temperature of the stiffener member.

Next for the fabrication process 1600, warpage may be determined 1604, for example using computer simulation employing finite element modeling techniques. Determination 1604 may be made for the first temperature of interest (e.g. reflow temperature.) Alternatively or additionally, determination may be made for a second temperature of interest. (e.g. room temperature.) As already discussed in detail previously herein, for warpage determination, lateral turning point warpage may be measurable from the central turning point of warpage to one of the lateral turning points of warpage. Alternatively or additionally, extremity warpage may be measurable from the central turning point of warpage to an extremity of the substrate.

Next for the fabrication process 1600, warpage may be compared 1606 to one or more predetermined values. For example one or more predetermined values may be compared to the determined extremity warpage and/or lateral turning point warpage. More generally, one or more predetermined values may be compared to the determined extremity warpage and/or lateral stationary point warpage. Then at decision block 1606 a decision may be made whether to modify one or more of the attributes/parameters of the stiffener member, based on the foregoing comparison indicating whether warpage is sufficiently mitigated by the selected stiffener attributes.

In the affirmative “yes” case, one or more of the attributes may be modified/adjusted so as to mitigate/reduce warpage and process 1600 may continue iteratively with once again determining 1605 warpage and comparing 1606 warpage, until a decision at decision block 1606 may be made in the negative “no” case that one or more of the attributes shall not be modified or further modified.

Once the decision at decision block 1606 may be made in the negative “no” case that the one or more of the attributes shall not be modified or further modified, then the process 1600 may continue with determination 1612 of selection of the one or more attributes. Once the selection of one or more attributes has been determined, then the process 1600 may continue with mounting 1616 the stiffener on the substrate surface, wherein the stiffen so mounted has the determined selected attributes for sufficiently mitigating/reducing warpage. Once the stiffener and chip are mounted on the substrate, the process 1600 can end.

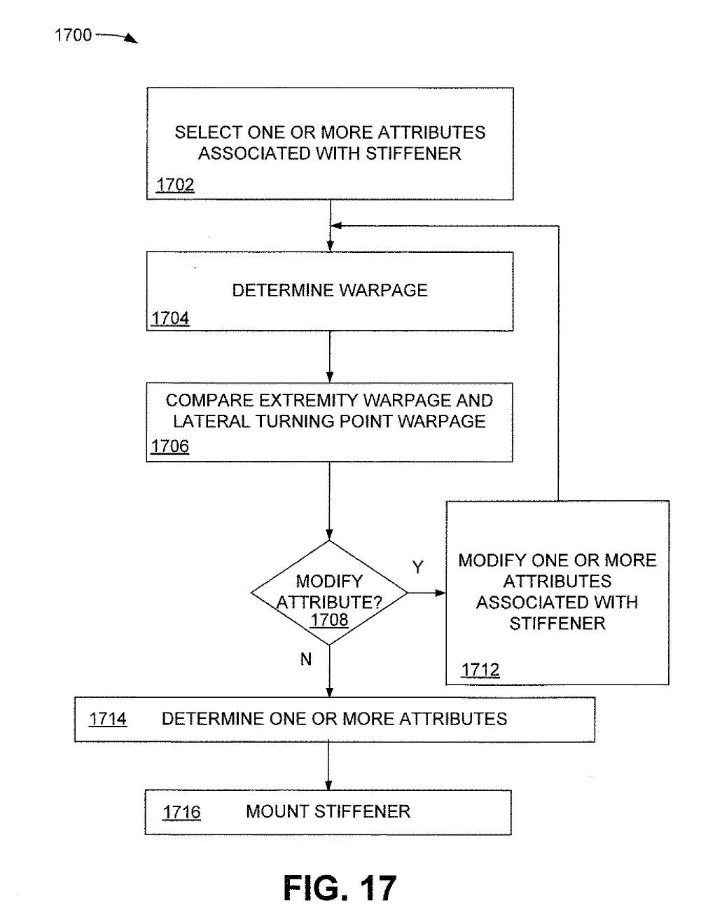

FIG. 17 is a flowchart describing the operation of another embodiment of the system and method for fabricating the package. A fabricating process 1700 according to another embodiment is shown in FIG. 17. The fabricating process 1700 may likewise be suitable for a chip and stiffener member to be mounted on a provided surface of a substrate of the package.

Initial procedures of selecting 1702 attributes and determining 1704 warpage in process 1700 are generally similar to corresponding procedures in process 1600 as just discussed. For the sake of brevity and clarity, reference is made for incorporation, without fully reproducing the previous discussion.

Next for the fabrication process 1700, extremity warpage and lateral turning point warpage may be compared 1706. For example, such comparison may indicate whether lateral turning point warpage measurable from the central turning point to one of the lateral turning points approximately overlaps extremity warpage measurable from the central turning point to an extremity of the substrate, for purposes of sufficient warpage mitigation. More generally, extremity warpage and lateral stationary point warpage may be compared 1706. Alternatively or additionally, such comparison may indicate whether extremity warpage measurable from the central turning point to an extremity of the substrate is sufficiently reduced so as to be approximately less than lateral turning point warpage measurable from the central turning point to one of the lateral turning points (or more generally, to one of the lateral stationary points), for purposes of sufficient warpage mitigation.

Alternatively or additionally, such comparison may indicate whether both extremity warpage measurable from the central turning point to an extremity of the substrate and lateral turning point warpage measurable from the central turning point to one of the lateral turning points are sufficiently reduced, for purposes of sufficient warpage mitigation.

Then at decision block 1706 a decision may be made whether to modify one or more of the attributes/parameters of the stiffener member, based on the foregoing comparison indicating whether warpage is sufficiently mitigated by the selected stiffener attributes

In the affirmative “yes” case, one or more of the attributes may be modified/adjusted so as to mitigate/reduce warpage and process 1700 may continue iteratively with once again determining 1705 warpage and comparing 1706 warpage, until a decision at decision block 1706 may be made in the negative “no” case that one or more of the attributes shall not be modified or further modified.

Once the decision at decision block 1706 may be made in the negative “no” case that the one or more of the attributes shall not be modified or further modified, then the process 1700 may continue with determination 1712 of selection of the one or more attributes. Once the selection of one or more attributes has been determined, then the process 1700 may continue with mounting 1716 the stiffener on the substrate surface, wherein the stiffen so mounted has the determined selected attributes for sufficiently mitigating/reducing warpage. Once the stiffener and chip are mounted on the substrate, the process 1700 can end.

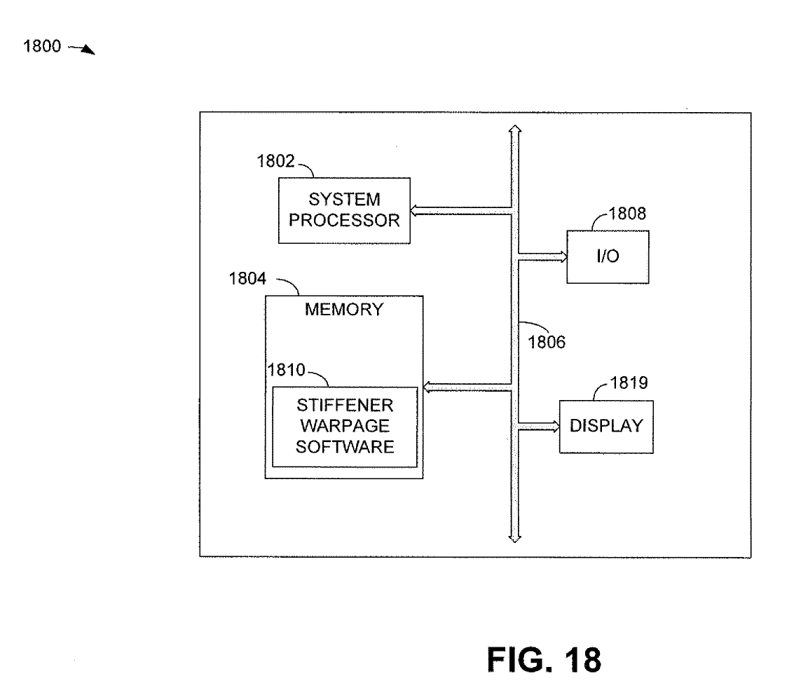

FIG. 18 is a block diagram illustrating an example general purpose computer system for implementing the system and method for fabricating the package. The computer system 1800 can be any general-purpose or computer system for executing instructions. In view of the disclosure herein, one of ordinary skill in programming is able to write computer code or identify appropriate hardware and/or circuits to implement the disclosed invention without difficulty based on the flow charts and associated description in this specification, for example. Therefore, disclosure of a particular set of program code instructions or detailed hardware devices is not considered necessary for an adequate understanding of how to make and use the invention. The inventive functionality of the claimed computer implemented processes is explained in more detail in the above description and in conjunction with the figures, which may illustrate various process flows.

In one or more exemplary aspects, the functions described may be implemented in hardware, software, firmware, or any combination thereof. If implemented in software, the functions may be stored on or transmitted as one or more instructions or code on a computer-readable medium. Computer-readable media include both computer storage media and communication media including any medium that facilitates transfer of a computer program from one place to another. A storage media may be any available media that may be accessed by a computer. By way of example, and not limitation, such computer-readable media may comprise RAM, ROM, EEPROM, CD-ROM or other optical disk storage, magnetic disk storage or other magnetic storage devices, or any other medium that may be used to carry or store desired program code in the form of instructions or data structures and that may be accessed by a computer.

Further, any connection is properly termed a computer-readable medium. For example, if the software is transmitted from a website, server, or other remote source using a coaxial cable, fiber optic cable, twisted pair, digital subscriber line (“DSL”), or wireless technologies such as infrared, radio, and microwave, then the coaxial cable, fiber optic cable, twisted pair, DSL, or wireless technologies such as infrared, radio, and microwave are included in the definition of medium.

The terms disk and disc, as used herein, includes compact disc (“CD”), laser disc, optical disc, digital versatile disc (“DVD”), floppy disk and blu-ray disc where disks usually reproduce data magnetically, while discs reproduce data optically with lasers. Combinations of the above should also be included within the scope of computer-readable media.

The system 1800 comprises a system processor 1802, which can be a general purpose or special purpose microprocessor, memory 1804, stiffener warpage mitigation software 1810, an input/output (I/O) element 1808 and a display 1818, operatively connected together over a system bus 1806. The system bus 1806 can include the physical and logical connections to couple the above-described elements together and enable their interoperability.

The I/O element 1808 can include, for example, a keyboard, a mouse, a pointing device, user interface control elements, and any other devices or systems that allow a user to provide input commands and receive outputs from the system 1800.

The memory 1804 can be any type of volatile or non-volatile memory, and in an embodiment, can include flash memory. The memory 1804 can be permanently installed in the system 1800, or can be a removable memory element, such as a removable memory card. The display 1812 can be a monitor or other device capable of providing a display to a user.

Although omitted from FIG. 18 for ease of illustration, the system 1800 also includes a power source, which can be an internal or external power source, and which can comprise, for example, an alternating current (AC) power adaptor or charger, a direct current (DC) adaptor or charger, a rechargeable power source, or another external or internal power source.

The system processor 1802 can be any processor that executes the stiffener warpage mitigation software 1810 for use fabricating the package described herein. The memory 1804 can be volatile or non-volatile memory, and in an embodiment, can be non-volatile memory that stores the stiffener warpage software mitigation 1810.

The I/O element 1808 may be used for entering the substrate properties of the package and the particular temperature of interest, as well as for entering and/or selecting and/or adjusting and/or modifying various parameters and/or various attributes associated with the stiffener member of the package. The foregoing may be provided to the system 1800 in such manner, or in another suitable manner for analysis by the system processor 1802 executing the stiffener warpage mitigation software 1810. The stiffener warpage mitigation software 1810 may comprise a warpage determination software module, which may perform simulation calculations, for example, using finite element modeling techniques, so as to determine package substrate warpage, and in particular so as to determine package substrate warpage as it may be affected by the selection of the various parameters and/or various attributes associated with the stiffener member of the package. Accordingly, it should be understood that the system 1800 shown in FIG. 18 may provide for automation of warpage determination.

The system 1800 shown in FIG. 18 may further provide for automation assistance in selection of parameters and/or attributes associated with the stiffener member for affecting warpage. The warpage determination software module of the stiffener warpage mitigation software 1810 may be configured to accept modification of at least one parameter corresponding to the stiffener member. As a non-limiting example, if the warpage exceeds a predetermined value, the stiffener warpage mitigation software 1810 may be configured to accept modification of at least one parameter corresponding to the stiffener member. The foregoing may facilitate modifying at least one attribute associated with the stiffener member.

Accordingly, if the foregoing analysis using stiffener warpage mitigation software 1810 reveals an unacceptable amount of warping at the particular temperature of interest, the parameters and/or attributes associated with the stiffener member for affecting warpage can be adjusted and recalculated to adjust and/or mitigate warpage, and the foregoing may be repeated until an acceptable amount of warpage is shown. Various parameters of the package and/or of the substrate and/or of the stiffener member affecting warpage as well as one or more warpage determinations, for example extremity warpage determination and/or lateral turning point warpage determination, may be displayed and/or illustratively represented to the user on the display 1819.

Further, the above described analysis can be performed on other computing devices, or can be done by hand.

Therefore, the system and method for fabricating the package can be performed in a number of ways, example embodiments being described herein.

The various aspects, features, embodiments or implementations of the invention described above can be used alone or in various combinations.

Different aspects, embodiments or implementations may, but need not, yield one or more of the following advantages. One advantage may be that package substrate warpage may be mitigated and/or reduced at a first temperature of interest, which may be a reflow temperature of solder for mounting the package. Alternatively or additionally package substrate warpage may be mitigated and/or reduced at a second temperature of interest, which may be room temperature. Another advantage may be accomplishing the foregoing while also limiting weight and/or volume added to the package by its stiffening member. Another advantage may be efficiency provided by automation of warpage determination and by automation assistance in selection of parameters and/or attributes associated with the stiffener member for affecting warpage.

The many features and advantages of the present invention are apparent from the written description. Further, since numerous modifications and changes will readily occur to those skilled in the art, the invention should not be limited to the exact construction and operation as illustrated and described. Hence, all suitable modifications and equivalents may be resorted to as falling within the scope of the invention.

What is claimed is:

1-18. (canceled)

19. A fabricating system comprising:
a substrate having a substrate surface;
a chip and a stiffener member mounted on the substrate surface so that the substrate has out-of-plane displacement at a first temperature of interest corresponding to warpage, wherein at least a portion of the substrate surface has substantially w-shaped warpage having a central turning point of warpage proximate to the chip and interposed between first and second lateral stationary points of warpage;
a warpage determination software module executing on a processor, wherein the warpage determination software module is configured to determine out-of-plane displacement at the first temperature of interest corresponding to warpage;
a first selected location proximate to one of the first and second lateral stationary points of the warpage, wherein the stiffener member is mounted at the first selected locations for mitigating warpage measurable from the central turning point, and wherein the warpage determination software module is configured to accept modification of at least one parameter corresponding to the stiffener member.

20. A fabricating system as recited in claim 19 wherein the warpage determination software module is configured to indicate mitigation of warpage measurable from the central turning point of warpage, based at least in part upon the modification of at least one parameter corresponding to the stiffener member.

21. A fabricating system as recited in claim 19 wherein, the modification of at least one parameter corresponding to the stiffener member comprises modification chosen from an attach temperature parameter, a thickness dimension parameter, a width dimension parameter, a first mounting location parameter, and a second mounting location parameter.

22. An apparatus comprising:
a substrate surface having out-of-plane displacement at a first temperature of interest corresponding to warpage, wherein at least a portion of the substrate surface has substantially w-shaped warpage having a central turning point of the warpage interposed between first and second lateral stationary points of the warpage;
a chip mounted proximate to the central turning point of the warpage on the portion of the substrate surface; and
a stiffener member mounted at a first selected location proximate to one of the first and second lateral stationary points of the warpage, so that warpage measurable from the central turning point to an extremity of the substrate is approximately less than warpage measurable from the central turning point to one of the lateral stationary points of warpage.

23. The apparatus as recited in claim 22 wherein warpage measurable from the central turning point to one of the lateral stationary points approximately overlaps warpage measurable from the central turning point to the extremity of the substrate.

24. The apparatus as recited in claim 22 wherein the first and second lateral stationary points comprise first and second lateral turning points or first and second lateral inflection points.

25. The apparatus as recited in claim 22 wherein the stiffener member is substantially annular having an outer perimeter and an inner perimeter.

26. The apparatus as recited in claim 25 wherein the stiffener member is shaped as a substantially square annulus.

27. The apparatus as recited in claim 26 wherein the outer perimeter comprises an outer diameter and wherein the inner perimeter comprises an inner diameter.

28. The apparatus as recited in claim 27 wherein the inner perimeter and outer perimeter of the stiffener member are arranged in a substantially concentric arrangement relative to a perimeter of the chip.

29. The apparatus as recited in claim 27 wherein the stiffening member is mounted on a first major surface of the substrate so that a portion of the outer perimeter is adjacent to a first selected surface location of the substrate.

30. The apparatus as recited in claim 29 wherein a portion of the inner perimeter is adjacent to a second selected surface location of the substrate.

31. The apparatus as recited in claim 30 wherein the second selected surface location is proximate to a perimeter of the chip.

32. The apparatus as recited in claim 27 wherein the stiffener member comprises a selected width dimension extending between the outer perimeter and the inner perimeter.

33. The apparatus as recited in claim 22 wherein the stiffener member is mounted to the substrate with a curable adhesive.

34. The apparatus as recited in claim 22 wherein the chip comprises an Integrated Circuit chip.

35. The apparatus as recited in claim 22 wherein the substrate comprises a multi-layer laminate structure.

36. The apparatus as recited in claim 22 wherein solder bumps are used to mount the chip to the substrate.

37. The apparatus as recited in claim 22 wherein the first temperature of interest corresponds to a reflow temperature of solder.

38. The apparatus as recited in claim 22 wherein the first temperature of interest corresponds to an adhesive curing temperature.
